(19) United States
(12) Patent Application Publication
(10) Pub. No.: US 2025/0253885 A1
(43) Pub. Date: Aug. 7, 2025

(54) AMPLIFIER CIRCUIT AND COMMUNICATION APPARATUS

(71) Applicant: Murata Manufacturing Co., Ltd., Kyoto (JP)

(72) Inventors: Kenji Tahara, Kyoto (JP); Kae Yamamoto, Kyoto (JP)

(21) Appl. No.: 19/088,066

(22) Filed: Mar. 24, 2025

Related U.S. Application Data
(63) Continuation of application No. PCT/JP2023/033567, filed on Sep. 14, 2023.

(30) Foreign Application Priority Data
Sep. 28, 2022 (JP) 2022-155480

(51) Int. Cl. H04B 1/401; H03F 1/02; H03F 3/21

(52) U.S. Cl. CPC H04B 1/401; H03F 1/0288; H03F 3/211; H03F 2200/451

(57) ABSTRACT

An amplifier circuit is an amplifier circuit that receives a plurality of discrete power supply voltages and includes a carrier amplifier, a peak amplifier, a combiner circuit that combines a high frequency signal outputted from the carrier amplifier and a high frequency signal outputted from the peak amplifier together, a bias circuit that supplies a first bias current to the peak amplifier, a digital control terminal that receives a digital control signal based on an envelope signal, and a switch that is connected to the digital control terminal and switches between connection and disconnection between the bias circuit and the peak amplifier. Each of the carrier amplifier and the peak amplifier includes a plurality of amplifier elements that are cascode-connected.

### CROSS REFERENCE TO RELATED APPLICATION

This is a continuation of International Application No. PCT/JP2023/033567 filed on Sep. 14, 2023 which claims priority from Japanese Patent Application No. 2022-155480 filed on Sep. 28, 2022. The contents of these applications are incorporated herein by reference in their entireties.

### BACKGROUND OF THE DISCLOSURE

### Field of the Disclosure

The present disclosure relates to an amplifier circuit and a communication apparatus.

### Description of the Related Art

In recent years, efficiency (power-added efficiency) has been improved by applying envelope tracking (ET) to power amplifier circuits. Regarding ET systems, digital ET technology that supplies power supply voltages having a plurality of discrete voltage levels has been disclosed.

In U.S. Pat. No. 9,755,672, a power supply modulation circuit (envelope tracking system) that supplies, based on an envelope signal, a power supply voltage to an amplifier circuit is disclosed. The power supply modulation circuit includes a switched-capacitor circuit that generates a plurality of voltages having different voltage levels and an output switch circuit that selects and outputs at least one of the plurality of voltages.

### BRIEF SUMMARY OF THE DISCLOSURE

However, in the case where a high frequency signal is amplified by an amplifier circuit using the digital ET disclosed in U.S. Pat. No. 9,755,672, it is assumed that the efficiency of the amplifier circuit degrades as the frequency of the high frequency signal increases.

Thus, the present disclosure provides an amplifier circuit and a communication apparatus in which the degradation of the efficiency in the case of using digital ET is suppressed.

An amplifier circuit according to an aspect of the present disclosure is an amplifier circuit that receives a plurality of discrete power supply voltages and includes a carrier amplifier, a first peak amplifier, a combiner circuit that combines a high frequency signal outputted from the carrier amplifier and a high frequency signal outputted from the first peak amplifier together, a bias circuit that supplies a first bias current to the first peak amplifier, a digital control terminal that receives a digital control signal based on an envelope signal, and a first switch that is connected to the digital control terminal and switches between connection and disconnection between the bias circuit and the first peak amplifier. Each of the carrier amplifier and the first peak amplifier includes a plurality of amplifier elements that are cascode-connected.

According to the present disclosure, an amplifier circuit and a communication apparatus in which the degradation of the efficiency in the case of using digital ET is suppressed can be provided.

### BRIEF DESCRIPTION OF THE SEVERAL VIEWS OF THE DRAWINGS

FIG. 1A is a graph indicating an example of transition of a power supply voltage in an average power tracking mode.

FIG. 1B is a graph indicating an example of transition of a power supply voltage in an analog envelope tracking mode.

FIG. 1C is a graph indicating an example of transition of a power supply voltage in a digital envelope tracking mode.

FIG. 2A is a circuit configuration diagram of an amplifier circuit and a communication apparatus according to an embodiment.

FIG. 2B is a diagram illustrating a logical value table for logic circuits in the embodiment and the relationship between a high frequency signal and a power supply voltage value.

FIG. 3A is a circuit configuration diagram of an amplifier circuit and a communication apparatus according to Modification 1.

FIG. 3B is a diagram illustrating a logical value table for logic circuits in Modification 1 and the relationship between a high frequency signal and a power supply voltage value.

FIG. 4 is a circuit configuration diagram of an amplifier circuit and a communication apparatus according to Modification 2.

FIG. 5A is a circuit configuration diagram of an amplifier circuit and a communication apparatus according to Modification 3.

FIG. 5B is a diagram illustrating a logical value table for logic circuits in Modification 3 and the relationship between a high frequency signal and a power supply voltage value.

FIG. 6A is a circuit state diagram for the case where an input power of the amplifier circuit according to Modification 3 has a third power value.

FIG. 6B is a circuit state diagram for the case where the input power of the amplifier circuit according to Modification 3 has a second power value.

FIG. 6C is a circuit state diagram for the case where the input power of the amplifier circuit according to Modification 3 has a first power value.

FIG. 7 includes graphs each indicating the relationship between an output power and a gain of the amplifier circuit according to Modification 3.

### DETAILED DESCRIPTION OF THE DISCLOSURE

Hereinafter, embodiments of the present disclosure will be described in detail with reference to the drawings. The embodiments described below each illustrate a comprehensive or specific example. Numerical values, shapes, materials, component elements, arrangements of the component elements, manners in which the component elements are connected, and so on illustrated in the embodiments described below are merely examples and are not intended to limit the present disclosure.

The drawings are schematic diagrams in which emphasis, omission, or ratio adjustment is performed in an appropriate manner in order that the present disclosure is illustrated. The drawings are not necessarily illustrated precisely and may differ from actual shapes, positional relationships, and ratios. In the drawings, substantially the same configurations are denoted by the same reference signs, and repetitive description may be omitted or simplified.

In a circuit configuration in the present disclosure, “being connected” not only represents being directly connected by a connection terminal and/or a wiring conductor but also includes being electrically connected with another circuit element interposed therebetween. “Being connected between A and B” represents being connected between A and B and to both A and B.

Furthermore, in the present disclosure, a “signal path” represents a transmission line including a wire through which a high frequency signal propagates, an electrode directly connected to the wire, a terminal directly connected to the wire or the electrode, and the like.

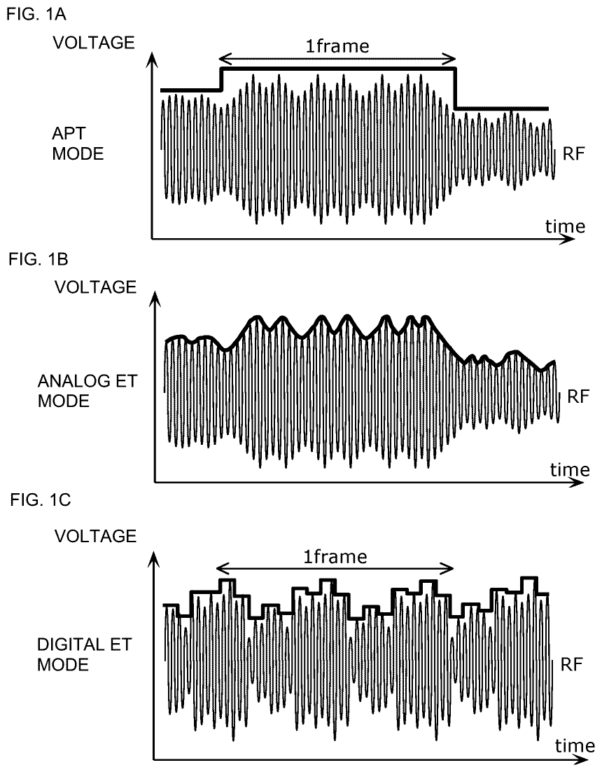

First, as a technique for amplifying a high frequency signal highly efficiently, tracking modes in which a variable power supply voltage that is dynamically adjusted with time on the basis of the high frequency signal is supplied to a power amplifier will be explained. The tracking modes are modes for dynamically adjusting a power supply voltage to be applied to an amplifier circuit. There are some types of tracking modes. An average power tracking (APT) mode and an envelope tracking (ET) mode (including an analog ET mode and a digital ET mode) will be explained below with reference to FIGS. 1A to 1C. In each of FIGS. 1A to 1C, the horizontal axis represents time and the vertical axis represents voltage. The thick solid line represents a power supply voltage and the thin solid line (waveform) represents a modulated wave.

FIG. 1A is a graph indicating an example of transition of a power supply voltage in the APT mode. In the APT mode, the power supply voltage is varied to a plurality of discrete voltage levels frame by frame. As a result, a power supply voltage signal forms a rectangular wave. In the APT mode, the voltage level of a power supply voltage is determined based on an average output power. In the APT mode, the voltage level may change in units smaller than one frame (for example, in units of subframes, slots, or symbols). APT in which the voltage level changes in units of symbols may be called symbol power tracking (SPT).

A frame is a unit of a high frequency signal with a length of 10 milliseconds. A frame includes ten subframes. A subframe is a unit of a high frequency signal with a length of 1 millisecond. A subframe includes two slots. A slot is a unit of a high frequency signal with a length of 0.5 milliseconds. A slot includes six symbols. A symbol is a unit of a high frequency signal with a length of 71 microseconds. A symbol includes a cyclic prefix (CP).

In an SPT mode, the level of a power supply voltage is modulated in units of one symbol. At this time, the voltage level is changed in a section of a CP. For example, in the first symbol, the voltage level is changed to a higher voltage level in a CP. In the second symbol, the voltage level is changed to a lower voltage level in a CP. In a subsequent symbol, the voltage level is not necessarily changed. The level of a power supply voltage can be modulated based on a data signal in each symbol section.

FIG. 1B is a graph indicating an example of transition of a power supply voltage in the analog ET mode. The analog ET mode is an example of a known ET mode. As illustrated in FIG. 1B, in the analog ET mode, the power supply voltage is continuously varied so that an envelope of a modulated wave can be tracked. In the analog ET mode, the power supply voltage is determined based on an envelope signal.

An envelope signal is a signal indicating an envelope of a modulated wave. An envelope value is expressed by, for example, the square root of (I2+Q2), where (I,Q) represents a constellation point. The constellation point is a point representing, on a constellation diagram, a signal modulated by digital modulation. (I,Q) is determined, for example, based on transmission information, by a baseband integrated circuit (BBIC).

FIG. 1C is a graph indicating an example of transition of a power supply voltage in the digital ET mode. As illustrated in FIG. 1C, in the digital ET mode, a power supply voltage is varied to a plurality of discrete voltage levels in one frame so that an envelope of a modulated wave can be tracked. As a result, a power supply voltage signal forms a rectangular wave. In the digital ET mode, the level of a power supply voltage is selected or set, based on an envelope signal, from among the plurality of discrete voltage levels.

### EMBODIMENT

### (1 Configuration of Amplifier Circuit 1 and Communication Apparatus 4)

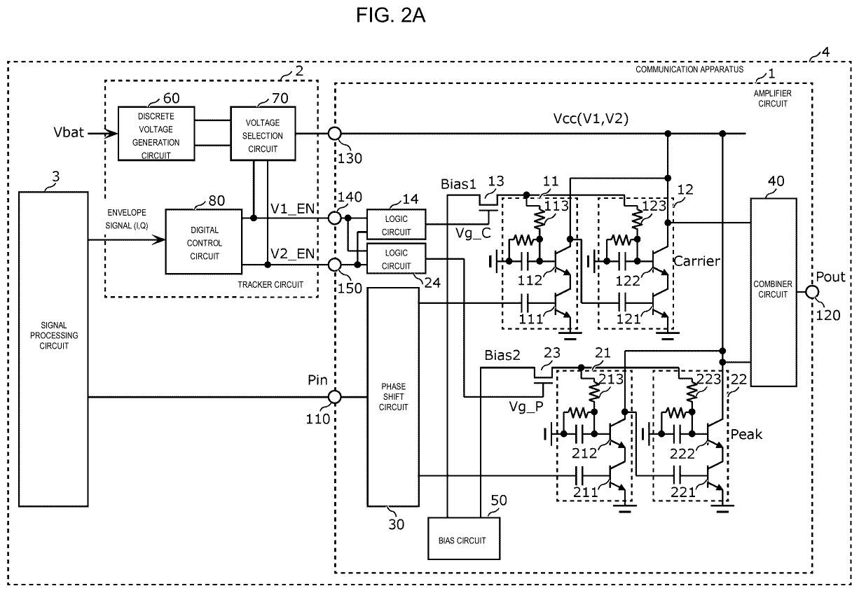

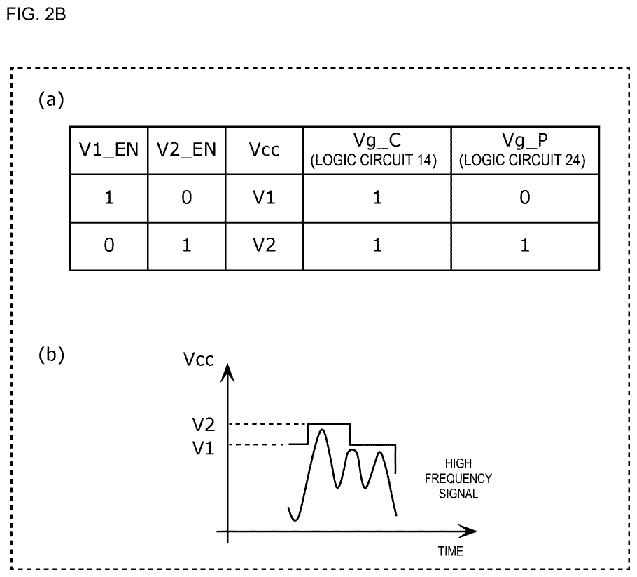

An amplifier circuit 1 and a communication apparatus 4 according to an embodiment will be described with reference to FIG. 2A.

FIG. 2A is a circuit configuration diagram of the amplifier circuit 1 and the communication apparatus 4 according to the embodiment. The communication apparatus 4 according to the embodiment corresponds to a user terminal (user equipment: UE) in a cellular network and is typically a cellular phone, a smartphone, a tablet computer, a wearable device, or the like. The communication apparatus 4 may be an Internet of things (IoT) sensor/device, a medical/healthcare device, a vehicle, an unmanned aerial vehicle (UAV) (the so-called drone), or an automated guided vehicle (AGV).

First, a circuit configuration of the communication apparatus 4 will be described. As illustrated in FIG. 2A, the communication apparatus 4 according to the embodiment includes the amplifier circuit 1, a tracker circuit 2, and a signal processing circuit 3.

The signal processing circuit 3 is an example of a signal processing circuit that processes a high frequency signal. The signal processing circuit 3 includes a controller that controls the amplifier circuit 1 and the tracker circuit 2. Specifically, the signal processing circuit 3 performs signal processing, by up-conversion or other processes, on a transmission signal and outputs a high frequency transmission signal generated by the signal processing to the amplifier circuit 1. The signal processing circuit 3 also outputs an envelope signal, which is a signal representing an envelope of a modulated wave of a high frequency signal, to the tracker circuit 2. Part of or the entire function of the controller of the signal processing circuit 3 may be implemented outside the signal processing circuit 3, for example, in the amplifier circuit 1 and the tracker circuit 2.

The tracker circuit 2 can supply a plurality of discrete power supply voltages based on a tracking mode to the amplifier circuit 1. The digital ET mode may be used as a tracking mode. However, the tracking mode is not limited to the digital ET mode. The tracker circuit 2 includes a discrete voltage generation circuit 60, a voltage selection circuit 70, and a digital control circuit 80.

The discrete voltage generation circuit 60 is configured to generate a plurality of discrete voltages having individual discrete voltage levels. The discrete voltage generation circuit 60 is, for example, a switched-capacitor circuit including a plurality of capacitors and a plurality of switches.

The voltage selection circuit 70 is configured to selectively output, based on an envelope signal, at least one of the plurality of discrete voltages generated by the discrete voltage generation circuit 60 to the amplifier circuit 1. The voltage selection circuit 70 is controlled on the basis of a digital control signal outputted from the digital control circuit 80.

The digital control circuit 80 is capable of controlling, based on an envelope signal from the signal processing circuit 3, the voltage selection circuit 70 and the amplifier circuit 1. Specifically, the digital control circuit 80 generates, based on an envelope signal received from the signal processing circuit 3, digital logic (digital control logic/line: DCL) signals (V1_EN, V2_EN).

The digital control circuit 80 is not necessarily included in the tracker circuit 2 but may be included in the signal processing circuit 3.

The amplifier circuit 1 includes carrier amplifiers 11 and 12, peak amplifiers 21 and 22, switches 13 and 23, logic circuits 14 and 24, a phase shift circuit 30, a combiner circuit 40, a bias circuit 50, a signal input terminal 110, a signal output terminal 120, a power supply voltage terminal 130, and digital control terminals 140 and 150.

The signal input terminal 110 is connected to the signal processing circuit 3 and the phase shift circuit 30 and transmits a high frequency signal outputted from the signal processing circuit 3 to the phase shift circuit 30. The signal output terminal 120 is connected to the combiner circuit 40 and an antenna (not illustrated in the drawing) and outputs a high frequency signal amplified by the amplifier circuit 1 to the antenna.

The power supply voltage terminal 130 is connected to the tracker circuit 2, the carrier amplifiers 11 and 12, and the peak amplifiers 21 and 22, and transmits a plurality of discrete power supply voltages that are generated by the tracker circuit 2 and are based on an envelope signal to the carrier amplifiers 11 and 12 and the peak amplifiers 21 and 22. The amplifier circuit 1 receives, via the power supply voltage terminal 130, a plurality of discrete power supply voltages from the tracker circuit 2.

The digital control terminals 140 and 150 receive digital control signals generated based on an envelope signal by the tracker circuit 2.

Each of the carrier amplifiers 11 and 12 and the peak amplifiers 21 and 22 includes an amplifying transistor. The amplifying transistor is, for example, a bipolar transistor such as a heterojunction bipolar transistor (HBT) or a field effect transistor such as a metal-oxide-semiconductor field effect transistor (MOSFET).

The carrier amplifiers 11 and 12 are Class A (or Class AB) amplifier circuits capable of amplifying operations for all the power levels of high frequency signals and, in particular, capable of a high-efficiency amplifying operation for a low output region and a medium output region. The carrier amplifiers 11 and 12 only need to be Class A (or Class AB) amplifier circuits and are not necessarily carrier amplifiers.

The peak amplifiers 21 and 22 are Class C amplifier circuits capable of an amplifying operation for a region in which the power level of a high frequency signal is high. Since a bias voltage lower than a bias voltage applied to the amplifying transistors included in the carrier amplifiers 11 and 12 is applied to the amplifying transistors included in the peak amplifiers 21 and 22, an output impedance decreases as the power level of a high frequency signal increases. Thus, the peak amplifiers 21 and 22 are capable of a low-distortion amplifying operation for a high output region. The peak amplifiers 21 and 22 only need to be Class C amplifier circuits and are not necessarily peak amplifiers.

The carrier amplifier 11 includes transistors 111 and 112 and a resistor 113. The transistors 111 and 112 are, for example, n-type bipolar transistors (amplifier elements). A base of the transistor 111 is connected to the phase shift circuit 30 with a capacitor interposed therebetween, an emitter of the transistor 111 is connected to the ground, and a collector of the transistor 111 is connected to an emitter of the transistor 112. A base of the transistor 112 is connected to the bias circuit 50 with the resistor 113 and the switch 13 interposed therebetween. Furthermore, the base of the transistor 112 is connected to the ground with a capacitor interposed therebetween and is grounded in a high-frequency manner. A collector of the transistor 112 is connected to the power supply voltage terminal 130. That is, the carrier amplifier 11 includes the transistors 111 and 112 that are cascode-connected.

The carrier amplifier 12 includes a transistor 121 (first amplifier element), a transistor 122 (second amplifier element), and a resistor 123. The transistors 121 and 122 are, for example, n-type bipolar transistors (amplifier elements). A base (first control terminal) of the transistor 121 is connected to the phase shift circuit 30 with a capacitor and the carrier amplifier 11 interposed therebetween, an emitter (first terminal) of the transistor 121 is connected to the ground, and a collector (second terminal) of the transistor 121 is connected to an emitter (third terminal) of the transistor 122. A base (second control terminal) of the transistor 122 is connected to the bias circuit 50 with the resistor 123 and the switch 13 interposed therebetween. Furthermore, the base of the transistor 122 is connected to the ground with a capacitor interposed therebetween and is grounded in a high-frequency manner. A collector (fourth terminal) of the transistor 122 is connected to the power supply voltage terminal 130 and is also connected to the combiner circuit 40. That is, the carrier amplifier 12 includes the transistors 121 and 122 that are cascode-connected.

The amplifier circuit 1 does not necessarily include the carrier amplifier 11. Furthermore, the amplifier circuit 1 includes the carrier amplifier 12 and may include three or more carrier amplifiers that are cascade-connected.

The peak amplifier 21 includes transistors 211 and 212 and a resistor 213. The transistors 211 and 212 are, for example, n-type bipolar transistors (amplifier elements). A base of the transistor 211 is connected to the phase shift circuit 30 with a capacitor interposed therebetween, an emitter of the transistor 211 is connected to the ground, and a collector of the transistor 211 is connected to an emitter of the transistor 212. A base of the transistor 212 is connected to the bias circuit 50 with the resistor 213 and the switch 23 interposed therebetween. Furthermore, the base of the transistor 212 is connected to the ground with a capacitor interposed therebetween and is grounded in a high-frequency manner. A collector of the transistor 212 is connected to the power supply voltage terminal 130. That is, the peak amplifier 21 includes the transistors 211 and 212 that are cascode-connected.

The peak amplifier 22 is an example of a first peak amplifier and includes a transistor 221 (third amplifier element), a transistor 222 (fourth amplifier element), and a resistor 223. The transistors 221 and 222 are, for example, n-type bipolar transistors (amplifier elements). A base (third control terminal) of the transistor 221 is connected to the phase shift circuit 30 with a capacitor and the peak amplifier 21 interposed therebetween, an emitter (fifth terminal) of the transistor 221 is connected to the ground, and a collector (sixth terminal) of the transistor 221 is connected to an emitter (seventh terminal) of the transistor 222. A base (fourth control terminal) of the transistor 222 is connected to the bias circuit 50 with the resistor 223 and the switch 23 interposed therebetween. Furthermore, the base of the transistor 222 is connected to the ground with a capacitor interposed therebetween and is grounded in a high-frequency manner. A collector (eighth terminal) of the transistor 222 is connected to the power supply voltage terminal 130 and is also connected to the combiner circuit 40. That is, the peak amplifier 22 includes the transistors 221 and 222 that are cascode-connected.

The amplifier circuit 1 does not necessarily include the peak amplifier 21. Furthermore, the amplifier circuit 1 includes the peak amplifier 22 and may include three or more peak amplifiers that are cascade-connected.

Since each of the carrier amplifiers 11 and 12 and the peak amplifiers 21 and 22 has a configuration of cascode connection, a high amplification gain can be ensured also for high frequency signals in a millimeter-wave band and a sub-terahertz band in the amplifier circuit 1.

The phase shift circuit 30 is configured to distribute high frequency signals inputted through the signal input terminal 110 and output the distributed signals to the carrier amplifier 11 and the peak amplifier 21. At this time, the phase shift circuit 30 adjusts the phases of the distributed signals. The amplifier circuit 1 does not necessarily include the phase shift circuit 30.

The combiner circuit 40 is configured to combine a high frequency signal outputted from the carrier amplifier 12 and a high frequency signal outputted from the peak amplifier 22 together and output the combined high frequency signal to the signal output terminal 120. The combiner circuit 40 may be a voltage combiner circuit using a transformer or a current combiner circuit using a phase shift line.

The bias circuit 50 is configured to supply bias currents to the carrier amplifiers 11 and 12 and the peak amplifiers 21 and 22. A first bias current is supplied via the switch 23 to the peak amplifiers 21 and 22, and a bias current is supplied via the switch 13 to the carrier amplifiers 11 and 12.

The switch 13 is connected to the digital control terminals 140 and 150 and switches between connection and disconnection between the bias circuit 50 and the carrier amplifiers 11 and 12. Specifically, the switch 13 includes a control terminal and two terminals. The control terminal is connected to the digital control terminals 140 and 150 with the logic circuit 14 interposed therebetween. One terminal is connected to the bias circuit 50 and the other terminal is connected to the carrier amplifiers 11 and 12.

The switch 23 is an example of a first switch. The switch 23 is connected to the digital control terminals 140 and 150 and switches between connection and disconnection between the bias circuit 50 and the peak amplifiers 21 and 22. Specifically, the switch 23 includes a control terminal and two terminals. The control terminal is connected to the digital control terminals 140 and 150 with the logic circuit 24 interposed therebetween. One terminal is connected to the bias circuit 50 and the other terminal is connected to the peak amplifiers 21 and 22.

The logic circuit 14 is connected between the switch 13 and the digital control terminals 140 and 150. The logic circuit 24 is connected between the switch 23 and the digital control terminals 140 and 150. For example, digital logic (digital control logic/line: DCL) signals (V1_EN, V2_EN) generated by the digital control circuit 80 of the tracker circuit 2 are applied to the digital control terminals 140 and 150.

Digital control signals supplied to the digital control terminals 140 and 150 are not serial data signals such as digital control signals of a source-synchronous type but are parallel data signals. Since the DCL signals V1_EN and V2_EN are supplied in a parallel manner to the digital control terminals 140 and 150, respectively, rapid variable supply of power supply voltages and rapid switching between ON and OFF of the peak amplifiers 21 and 22 can be achieved. Thus, a wide channel band width of high frequency signals in a millimeter-wave band and a sub-terahertz band can be supported.

Serial data signals represent data signals each of which is transmitted bit by bit on a single signal line or a single line. Parallel data signals represent data signals transmitted in a parallel manner at the same time on a plurality of signal lines or a plurality of lines.

FIG. 2B is a diagram illustrating a logical value table for the logic circuits 14 and 24 in the embodiment and the relationship between a high frequency signal and a power supply voltage value. In part (a) of FIG. 2B, a power supply voltage (V1 or V2) applied based on a DCL signal (V1_EN, V2_EN) to the power supply voltage terminal 130 is indicated, and a gate signal (Vg_C) and a gate signal (Vg P) outputted based on DCL signals (V1_EN, V2_EN) from the logic circuit 14 and the logic circuit 24, respectively, are indicated. Furthermore, in part (b) of FIG. 2B, a power supply voltage (V1 or V2) supplied to the amplifier circuit 1 with respect to an envelope of a high frequency signal inputted to the amplifier circuit 1 is indicated.

As illustrated in FIG. 2B, when the DCL signal V1_EN is 1 and the DCL signal V2_EN is 0, the voltage selection circuit 70 outputs the power supply voltage V1 to the power supply voltage terminal 130, the logic circuit 14 outputs a gate signal (Vg_C=1) that allows the switch 13 to be electrically connected, and the logic circuit 24 outputs a gate signal (Vg P=0) that allows the switch 23 to be electrically disconnected. Furthermore, when the DCL signal V1_EN is 0 and the DCL signal V2_EN is 1, the voltage selection circuit 70 outputs the power supply voltage V2 to the power supply voltage terminal 130, the logic circuit 14 outputs a gate signal (Vg_C=1) that allows the switch 13 to be electrically connected, and the logic circuit 24 outputs a gate signal (Vg P=1) that allows the switch 23 to be electrically connected.

That is, in the case where the envelope value (the square root of (I²+Q²)) of a high frequency signal inputted to the amplifier circuit 1 is relatively large (when a large signal is inputted: second power value), the amplifier circuit 1 receives the power supply voltage V2, which is larger than the power supply voltage V1, and the carrier amplifiers 11 and 12 and the peak amplifiers 21 and 22 that are supplied with bias currents from the bias circuit 50 enter an ON state. In this case, an output impedance when a load side is seen from output terminals of the carrier amplifier 12 and the peak amplifier 22 is represented by R_{L}.

Furthermore, in the case where the envelope value (the square root of (I²+Q²)) of a high frequency signal inputted to the amplifier circuit 1 is relatively small (when a small signal is inputted: first power value), the amplifier circuit 1 receives the power supply voltage V1, the carrier amplifiers 11 and 12 that are supplied with a bias current from the bias circuit 50 enter an ON state, and the peak amplifiers 21 and 22 that are not supplied with a bias current from the bias circuit 50 enter an OFF state. In this case, an impedance when the load side is seen from the output terminal of the carrier amplifier 12 is represented by 2R_{L}. At this time, an impedance when the load side is seen from the output terminal of the peak amplifier 22 is in an open state.

As described above, the impedance when the load side is seen from the carrier amplifier 12 at the time when a small signal is inputted is twice as much as the impedance when the load side is seen from the carrier amplifier 12 at the time when a large signal is inputted. That is, when a small signal is inputted, the peak amplifiers 21 and 22 enter the OFF state, and the impedance when the load side is seen from the carrier amplifier 12 increases. Therefore, the amplifier circuit 1 can operate with high efficiency.

In contrast, when a large signal is inputted, a large power signal can be outputted since the carrier amplifiers 11 and 12 and the peak amplifiers 21 and 22 operate in the state in which the power supply voltage is large, and signal distortion can be suppressed since the impedance when the load side is seen from the peak amplifier 22 is low.

Accordingly, since the supply of the first bias current to the peak amplifiers 21 and 22 is controlled on the basis of an envelope signal, efficiency is optimized based on an output power of the amplifier circuit 1. Furthermore, since both the supply of a power supply voltage and switching between ON and OFF of the peak amplifiers 21 and 22 are performed on the basis of an envelope signal, the efficiency of the amplifier circuit 1 can be optimized with high accuracy.

A bias current is supplied, based on electrical connection and electrical disconnection of the switch 13, to the bases of the transistor 112 of the carrier amplifier 11 and the transistor 122 of the carrier amplifier 12. Furthermore, a bias current is supplied, based on electrical connection and electrical disconnection of the switch 23, to the bases of the transistor 212 of the peak amplifier 21 and the transistor 222 of the peak amplifier 22. In contrast, a bias current is continuously supplied to the bases of the transistor 111 of the carrier amplifier 11, the transistor 121 of the carrier amplifier 12, the transistor 211 of the peak amplifier 21, and the transistor 221 of the peak amplifier 22, regardless of whether the switches 13 and 23 are electrically connected or electrically disconnected.

### (2 Configuration of Amplifier Circuit 1A and Communication Apparatus 4A According to Modification 1)

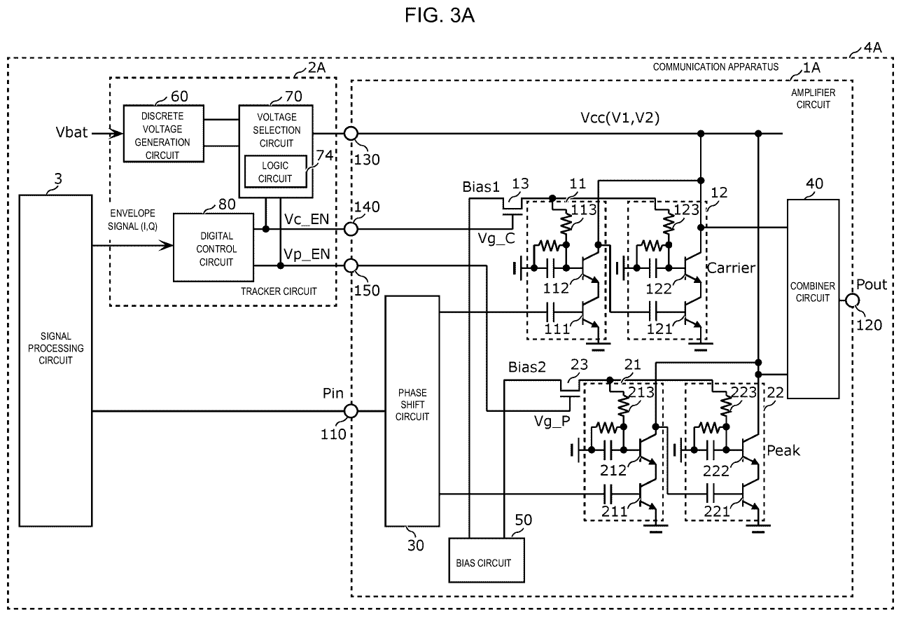

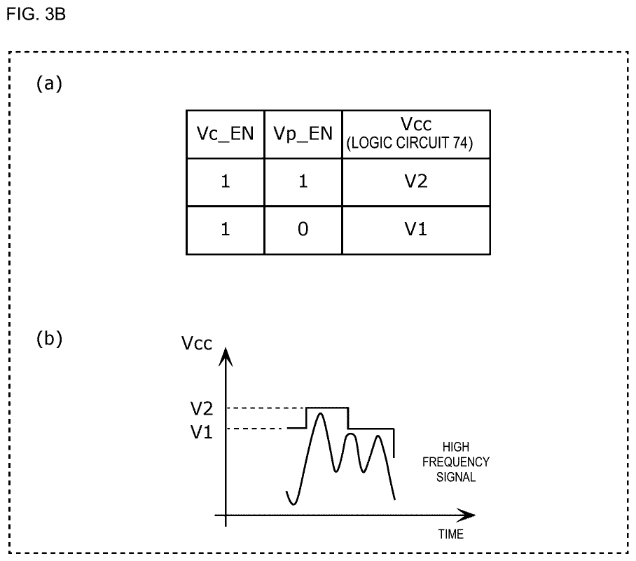

FIG. 3A is a circuit configuration diagram of an amplifier circuit 1A and a communication apparatus 4A according to Modification 1. The communication apparatus 4A according to this modification includes the amplifier circuit 1A, a tracker circuit 2A, and a signal processing circuit 3. The communication apparatus 4A according to this modification is different from the communication apparatus 4 according to the embodiment in that a logic circuit is not provided in the amplifier circuit 1A but is provided in the tracker circuit 2A. Hereinafter, the description of the configuration features of the communication apparatus 4A according to this modification that are the same as those of the communication apparatus 4 according to the embodiment will be omitted, and different configuration features will be mainly described.

The tracker circuit 2A includes a discrete voltage generation circuit 60, a voltage selection circuit 70, and a digital control circuit 80.

The voltage selection circuit 70 is configured to selectively output, based on an envelope signal, at least one of a plurality of discrete voltages generated by the discrete voltage generation circuit 60 to the amplifier circuit 1A. The voltage selection circuit 70 includes a logic circuit 74 and is controlled on the basis of a digital control signal outputted from the digital control circuit 80.

The digital control circuit 80 generates, based on an envelope signal received from the signal processing circuit 3, DCL signals (Vc_EN, Vp_EN).

The digital control circuit 80 is not necessarily included in the tracker circuit 2A but may be included in the signal processing circuit 3.

The amplifier circuit 1A includes carrier amplifiers 11 and 12, peak amplifiers 21 and 22, switches 13 and 23, a phase shift circuit 30, a combiner circuit 40, a bias circuit 50, a signal input terminal 110, a signal output terminal 120, a power supply voltage terminal 130, and digital control terminals 140 and 150.

The digital control terminals 140 and 150 receive digital control signals generated based on an envelope signal by the tracker circuit 2A.

The switch 13 is connected to the digital control terminals 140 and 150 and switches between connection and disconnection between the bias circuit 50 and the carrier amplifiers 11 and 12. Specifically, the switch 13 includes a control terminal and two terminals. The control terminal is connected to the digital control terminal 140. One terminal is connected to the bias circuit 50 and the other terminal is connected to the carrier amplifiers 11 and 12.

The switch 23 is an example of a first switch. The switch 23 is connected to the digital control terminals 140 and 150 and switches between connection and disconnection between the bias circuit 50 and the peak amplifiers 21 and 22. Specifically, the switch 23 includes a control terminal and two terminals. The control terminal is connected to the digital control terminal 150. One terminal is connected to the bias circuit 50 and the other terminal is connected to the peak amplifiers 21 and 22.

The logic circuit 74 is included in the voltage selection circuit 70. For example, the DCL signals (Vc_EN, Vp_EN) generated by the digital control circuit 80 of the tracker circuit 2A are applied to the digital control terminals 140 and 150.

FIG. 3B is a diagram illustrating a logical value table for the logic circuit 74 in Modification 1 and the relationship between a high frequency signal and a power supply voltage value. In part (a) of FIG. 3B, a power supply voltage (V1 or V2) applied based on a DCL signal (Vc_EN, Vp_EN) to the power supply voltage terminal 130 is indicated. Furthermore, in part (b) of FIG. 3B, a power supply voltage (V1 or V2) supplied to the amplifier circuit 1A with respect to an envelope of a high frequency signal inputted to the amplifier circuit 1A is indicated.

As illustrated in FIG. 3B, when the DCL signal Vc_EN is 1 and the DCL signal Vp_EN is 1, the voltage selection circuit 70 outputs the power supply voltage V2 that is larger than the power supply voltage V1 to the power supply voltage terminal 130. Furthermore, the switch 13 becomes electrically connected when the DCL signal Vc_EN is 1 and the switch 23 becomes electrically connected when the DCL signal Vp_EN is 1.

That is, in the case where the envelope value (the square root of (I²+Q²)) of a high frequency signal inputted to the amplifier circuit 1A is relatively large (when a large signal is inputted: second power value), the amplifier circuit 1A receives the power supply voltage V2, and the carrier amplifiers 11 and 12 and the peak amplifiers 21 and 22 that are supplied with bias currents from the bias circuit 50 enter an ON state. In this case, an impedance when a load side is seen from output terminals of the carrier amplifier 12 and the peak amplifier 22 is represented by R_{L}.

Furthermore, in the case where the envelope value (the square root of (I²+Q²)) of a high frequency signal inputted to the amplifier circuit 1A is relatively small (when a small signal is inputted: first power value), the amplifier circuit 1A receives the power supply voltage V1, the carrier amplifiers 11 and 12 that are supplied with a bias current from the bias circuit 50 enter an ON state, and the peak amplifiers 21 and 22 that are not supplied with a bias current from the bias circuit 50 enter an OFF state. In this case, an impedance when the load side is seen from the output terminal of the carrier amplifier 12 is represented by 2R_{L}. At this time, an impedance when the load side is seen from the output terminal of the peak amplifier 22 is in an open state.

As described above, the impedance when the load side is seen from the carrier amplifier 12 at the time when a small signal is inputted is twice as much as the impedance when the load side is seen from the carrier amplifier 12 at the time when a large signal is inputted. That is, when a small signal is inputted, the peak amplifiers 21 and 22 enter the OFF state, and the impedance when the load side is seen from the carrier amplifier 12 increases. Therefore, the amplifier circuit 1A can operate with high efficiency.

In contrast, when a large signal is inputted, a large power signal can be outputted since the carrier amplifiers 11 and 12 and the peak amplifiers 21 and 22 operate in the state in which the power supply voltage is large, and signal distortion can be suppressed since the impedance when the load side is seen from the peak amplifier 22 is low.

Accordingly, since the supply of the first bias current to the peak amplifiers 21 and 22 is controlled on the basis of an envelope signal, efficiency is optimized based on an output power of the amplifier circuit 1A. Furthermore, since both the supply of a power supply voltage and switching between ON and OFF of the peak amplifiers 21 and 22 are performed on the basis of an envelope signal, the efficiency of the amplifier circuit 1A can be optimized with high accuracy.

### (3 Configuration of Amplifier Circuit 1B and Communication Apparatus 4B According to Modification 2)

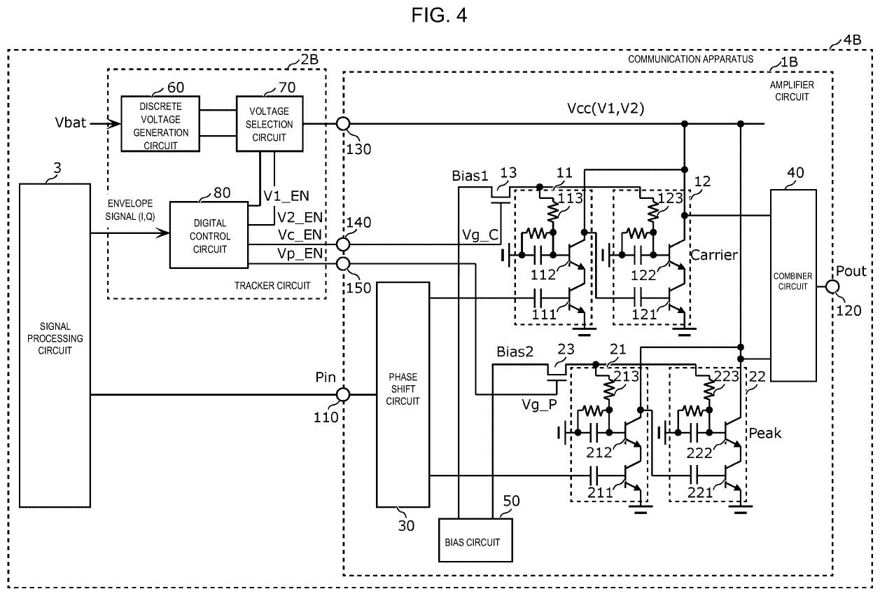

FIG. 4 is a circuit configuration diagram of an amplifier circuit 1B and a communication apparatus 4B according to Modification 2. The communication apparatus 4B according to this modification includes the amplifier circuit 1B, a tracker circuit 2B, and a signal processing circuit 3. The communication apparatus 4B according to this modification is different from the communication apparatus 4 according to the embodiment in a configuration of the digital control circuit 80 and in that no logic circuit is provided in the amplifier circuit 1B. Hereinafter, the description of the configuration features of the communication apparatus 4B according to this modification that are the same as those of the communication apparatus 4 according to the embodiment will be omitted, and different configuration features will be mainly described.

The tracker circuit 2B includes a discrete voltage generation circuit 60, a voltage selection circuit 70, and a digital control circuit 80.

The digital control circuit 80 generates, based on an envelope signal received from the signal processing circuit 3, DCL signals (V1_EN, V2_EN, Vc_EN, Vp_EN).

The digital control circuit 80 is not necessarily included in the tracker circuit 2B but may be included in the signal processing circuit 3.

The amplifier circuit 1B includes carrier amplifiers 11 and 12, peak amplifiers 21 and 22, switches 13 and 23, a phase shift circuit 30, a combiner circuit 40, a bias circuit 50, a signal input terminal 110, a signal output terminal 120, a power supply voltage terminal 130, and digital control terminals 140 and 150.

The digital control terminals 140 and 150 receive digital control signals generated based on an envelope signal by the tracker circuit 2B.

The switch 13 is connected to the digital control terminals 140 and 150 and switches between connection and disconnection between the bias circuit 50 and the carrier amplifiers 11 and 12. Specifically, the switch 13 includes a control terminal and two terminals. The control terminal is connected to the digital control terminal 140. One terminal is connected to the bias circuit 50 and the other terminal is connected to the carrier amplifiers 11 and 12.

The switch 23 is an example of a first switch. The switch 23 is connected to the digital control terminals 140 and 150 and switches between connection and disconnection between the bias circuit 50 and the peak amplifiers 21 and 22. Specifically, the switch 23 includes a control terminal and two terminals. The control terminal is connected to the digital control terminal 150. One terminal is connected to the bias circuit 50 and the other terminal is connected to the peak amplifiers 21 and 22.

For example, the DCL signals (Vc_EN, Vp_EN) generated by the digital control circuit 80 are applied to the digital control terminals 140 and 150. Furthermore, the DCL signals (V1_EN, V2_EN) generated by the digital control circuit 80 are applied to the voltage selection circuit 70.

When the DCL signal Vc_EN is 1, the switch 13 becomes electrically connected. When the DCL signal Vp_EN is 1, the switch 23 becomes electrically connected. When the DCL signal V1_EN is 1, the voltage selection circuit 70 outputs a power supply voltage V1 to the power supply voltage terminal 130. When the DCL signal V2_EN is 1, the voltage selection circuit 70 outputs a power supply voltage V2 to the power supply voltage terminal 130.

In the case where the envelope value (the square root of (I²+Q²)) of a high frequency signal inputted to the amplifier circuit 1B is relatively large (when a large signal is inputted: second power value), the digital control circuit 80 outputs the DCL signals V2_EN=1, V1_EN=0, Vc_EN=1, and Vp_EN=1. Therefore, the amplifier circuit 1B receives the power supply voltage V2, which is larger than the power supply voltage V1, and the carrier amplifiers 11 and 12 and the peak amplifiers 21 and 22 that are supplied with bias currents from the bias circuit 50 enter an ON state. In this case, an impedance when a load side is seen from output terminals of the carrier amplifier 12 and the peak amplifier 22 is represented by R_{L}.

Furthermore, in the case where the envelope value (the square root of (I²+Q²)) of a high frequency signal inputted to the amplifier circuit 1B is relatively small (when a small signal is inputted: first power value), the digital control circuit 80 outputs the DCL signals V2_EN=0, V1_EN=1, Vc_EN=1, and Vp_EN=0. Therefore, the amplifier circuit 1B receives the power supply voltage V1, the carrier amplifiers 11 and 12 that are supplied with a bias current from the bias circuit 50 enter an ON state, and the peak amplifiers 21 and 22 that are not supplied with a bias current from the bias circuit 50 enter an OFF state. In this case, an impedance when the load side is seen from the output terminal of the carrier amplifier 12 is represented by 2R_{L}. At this time, an impedance when the load side is seen from the output terminal of the peak amplifier 22 is in an open state.

As described above, the impedance when the load side is seen from the carrier amplifier 12 at the time when a small signal is inputted is twice as much as the impedance when the load side is seen from the carrier amplifier 12 at the time when a large signal is inputted. That is, when a small signal is inputted, the peak amplifiers 21 and 22 enter the OFF state, and the impedance when the load side is seen from the carrier amplifier 12 increases. Therefore, the amplifier circuit 1B can operate with high efficiency.

In contrast, when a large signal is inputted, a large power signal can be outputted since the carrier amplifiers 11 and 12 and the peak amplifiers 21 and 22 operate in the state in which the power supply voltage is large, and signal distortion can be suppressed since the impedance when the load side is seen from the peak amplifier 22 is low.

Accordingly, since the supply of the first bias current to the peak amplifiers 21 and 22 is controlled on the basis of an envelope signal, efficiency is optimized based on an output power of the amplifier circuit 1B. Furthermore, since both the supply of a power supply voltage and switching between ON and OFF of the peak amplifiers 21 and 22 are performed on the basis of an envelope signal, the efficiency of the amplifier circuit 1B can be optimized with high accuracy.

### (4 Configuration of Amplifier Circuit 1C and Communication Apparatus 4C According to Modification 3)

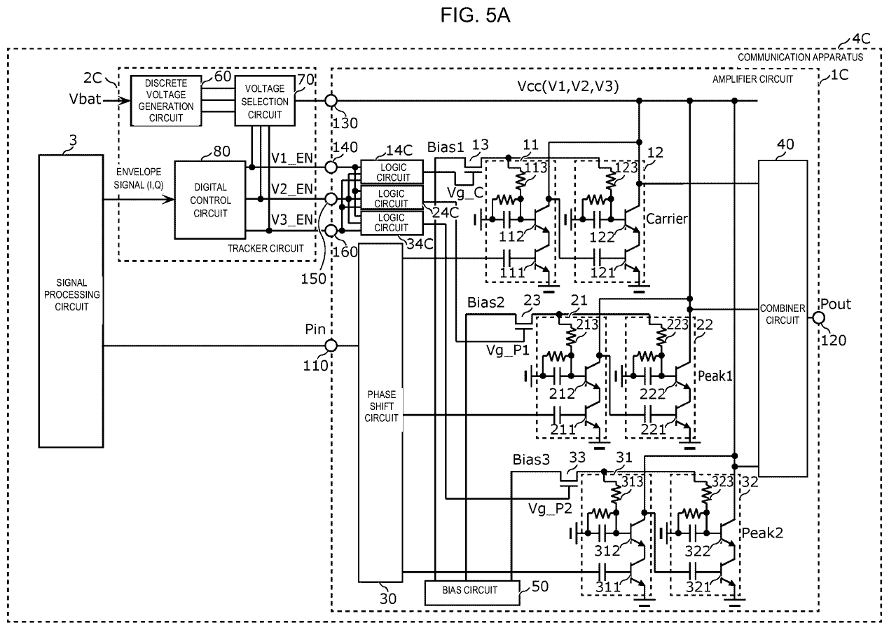

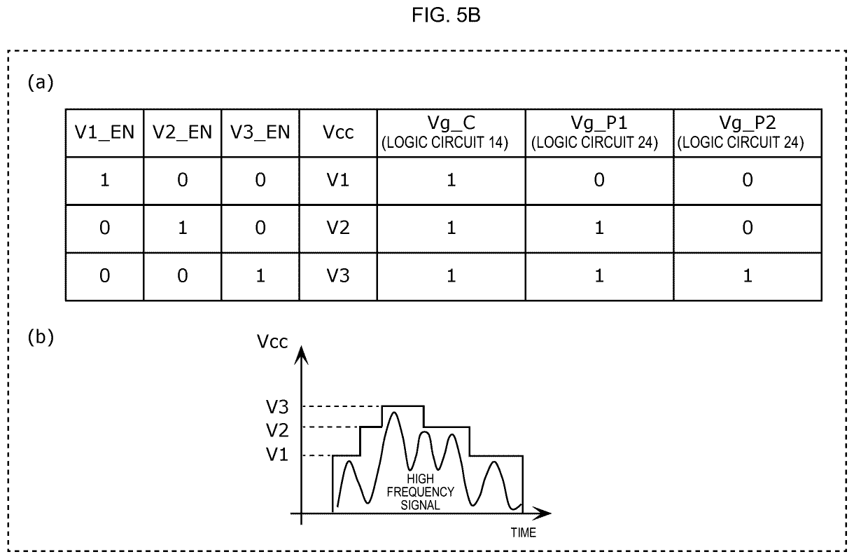

FIG. 5A is a circuit configuration diagram of an amplifier circuit 1C and a communication apparatus 4C according to Modification 3. The communication apparatus 4C according to this modification includes the amplifier circuit 1C, a tracker circuit 2C, and a signal processing circuit 3. The communication apparatus 4C according to this modification is different from the communication apparatus 4 according to the embodiment mainly in an amplifier configuration of the amplifier circuit 1C. Hereinafter, the description of the configuration features of the communication apparatus 4C according to this modification that are the same as those of the communication apparatus 4 according to the embodiment will be omitted, and different configuration features will be mainly described.

The tracker circuit 2C can supply a plurality of discrete power supply voltages based on a tracking mode to the amplifier circuit 1C. The digital ET mode may be used as a tracking mode. However, the tracking mode is not limited to the digital ET mode. The tracker circuit 2C includes a discrete voltage generation circuit 60, a voltage selection circuit 70, and a digital control circuit 80.

The digital control circuit 80 is capable of controlling, based on an envelope signal from the signal processing circuit 3, the voltage selection circuit 70 and the amplifier circuit 1C. Specifically, the digital control circuit 80 generates, based on an envelope signal received from the signal processing circuit 3, DCL signals (V1_EN, V2_EN, V3_EN).

The digital control circuit 80 is not necessarily included in the tracker circuit 2C but may be included in the signal processing circuit 3.

The amplifier circuit 1C includes carrier amplifiers 11 and 12, peak amplifiers 21, 22, 31, and 32, switches 13, 23, and 33, logic circuits 14C, 24C, and 34C, a phase shift circuit 30, a combiner circuit 40, a bias circuit 50, a signal input terminal 110, a signal output terminal 120, a power supply voltage terminal 130, and digital control terminals 140, 150, and 160.

The power supply voltage terminal 130 is connected to the tracker circuit 2C, the carrier amplifiers 11 and 12, and the peak amplifiers 21, 22, 31, and 32 and transmits a plurality of discrete power supply voltages that are generated by the tracker circuit 2C and are based on an envelope signal to the carrier amplifiers 11 and 12 and the peak amplifiers 21, 22, 31, and 32. The amplifier circuit 1C receives, via the power supply voltage terminal 130, a plurality of discrete power supply voltages from the tracker circuit 2C.

The digital control terminals 140, 150, and 160 receive digital control signals generated based on an envelope signal by the tracker circuit 2C.

Each of the carrier amplifiers 11 and 12 and the peak amplifiers 21, 22, 31, and 32 includes an amplifying transistor. The amplifying transistor is, for example, a bipolar transistor such as an HBT or a field effect transistor such as a MOSFET.

The peak amplifiers 21 and 22 are Class C amplifier circuits capable of an amplifying operation for a region in which the power level of a high frequency signal is high. Since a bias voltage lower than a bias voltage applied to the amplifying transistors included in the carrier amplifiers 11 and 12 is applied to the amplifying transistors included in the peak amplifiers 21 and 22, an output impedance decreases as the power level of a high frequency signal increases. Thus, the peak amplifiers 21 and 22 are capable of a low-distortion amplifying operation for a medium output region. The peak amplifiers 21 and 22 only need to be Class C amplifier circuits and are not necessarily peak amplifiers.

The peak amplifiers 31 and 32 are Class C amplifier circuits capable of an amplifying operation for a region in which the power level of a high frequency signal is high. Since a bias voltage lower than a bias voltage applied to the amplifying transistors included in the carrier amplifiers 11 and 12 is applied to the amplifying transistors included in the peak amplifiers 31 and 32, an output impedance decreases as the power level of a high frequency signal increases. Thus, the peak amplifiers 31 and 32 are capable of a low-distortion amplifying operation for a high output region. The peak amplifiers 31 and 32 only need to be Class C amplifier circuits and are not necessarily peak amplifiers.

The peak amplifier 31 includes transistors 311 and 312 and a resistor 313. The transistors 311 and 312 are, for example, n-type bipolar transistors (amplifier elements). A base of the transistor 311 is connected to the phase shift circuit 30 with a capacitor interposed therebetween, an emitter of the transistor 311 is connected to the ground, and a collector of the transistor 311 is connected to an emitter of the transistor 312. A base of the transistor 312 is connected to the bias circuit 50 with the resistor 313 and the switch 33 interposed therebetween. Furthermore, the base of the transistor 312 is connected to the ground with a capacitor interposed therebetween and is grounded in a high-frequency manner. A collector of the transistor 312 is connected to the power supply voltage terminal 130. That is, the peak amplifier 31 includes the transistors 311 and 312 that are cascode-connected.

The peak amplifier 32 is an example of a second peak amplifier and includes transistors 321 and 322 and a resistor 323. The transistors 321 and 322 are, for example, n-type bipolar transistors (amplifier elements). A base of the transistor 321 is connected to the phase shift circuit 30 with a capacitor and the peak amplifier 31 interposed therebetween, an emitter of the transistor 321 is connected to the ground, and a collector of the transistor 321 is connected to an emitter of the transistor 322. A base of the transistor 322 is connected to the bias circuit 50 with the resistor 323 and the switch 33 interposed therebetween. Furthermore, the base of the transistor 322 is connected to the ground with a capacitor interposed therebetween and is grounded in a high-frequency manner. A collector of the transistor 322 is connected to the power supply voltage terminal 130 and is also connected to the combiner circuit 40. That is, the peak amplifier 32 includes the transistors 321 and 322 that are cascode-connected.

The amplifier circuit 1C does not necessarily include the peak amplifier 31. Furthermore, the amplifier circuit 1C includes the peak amplifier 32 and may include three or more peak amplifiers that are cascade-connected.

Since each of the carrier amplifiers 11 and 12 and the peak amplifiers 21, 22, 31, and 32 has a configuration of cascode connection, a high amplification gain can be ensured also for high frequency signals in a millimeter-wave band and a sub-terahertz band in the amplifier circuit 1C.

The phase shift circuit 30 is configured to distribute high frequency signals inputted through the signal input terminal 110 and output the distributed signals to the carrier amplifier 11 and the peak amplifiers 21 and 31. At this time, the phase shift circuit 30 adjusts the phases of the distributed signals.

The combiner circuit 40 is configured to combine a high frequency signal outputted from the carrier amplifier 12, a high frequency signal outputted from the peak amplifier 22, and a high frequency signal outputted from the peak amplifier 32 together and output the combined high frequency signal to the signal output terminal 120.

The bias circuit 50 is configured to supply bias currents to the carrier amplifiers 11 and 12 and the peak amplifiers 21, 22, 31, and 32. A first bias current is supplied via the switch 23 to the peak amplifiers 21 and 22, a second bias current is supplied via the switch 33 to the peak amplifiers 31 and 32, and a bias current is supplied via the switch 13 to the carrier amplifiers 11 and 12.

The switch 13 is connected to the digital control terminals 140, 150, and 160 and switches between connection and disconnection between the bias circuit 50 and the carrier amplifiers 11 and 12. Specifically, the switch 13 includes a control terminal and two terminals. The control terminal is connected to the digital control terminals 140, 150, and 160 with the logic circuit 14C interposed therebetween. One terminal is connected to the bias circuit 50 and the other terminal is connected to the carrier amplifiers 11 and 12.

The switch 23 is an example of a first switch. The switch 23 is connected to the digital control terminals 140, 150, and 160 and switches between connection and disconnection between the bias circuit 50 and the peak amplifiers 21 and 22. Specifically, the switch 23 includes a control terminal and two terminals. The control terminal is connected to the digital control terminals 140, 150, and 160 with the logic circuit 24C interposed therebetween. One terminal is connected to the bias circuit 50 and the other terminal is connected to the peak amplifiers 21 and 22.

The switch 33 is an example of a second switch. The switch 33 is connected to the digital control terminals 140, 150, and 160 and switches between connection and disconnection between the bias circuit 50 and the peak amplifiers 31 and 32. Specifically, the switch 33 includes a control terminal and two terminals. The control terminal is connected to the digital control terminals 140, 150, and 160 with the logic circuit 34C interposed therebetween. One terminal is connected to the bias circuit 50 and the other terminal is connected to the peak amplifiers 31 and 32.

The logic circuit 14C is connected between the switch 13 and the digital control terminals 140, 150, and 160. The logic circuit 24C is connected between the switch 23 and the digital control terminals 140, 150, and 160. The logic circuit 34C is connected between the switch 33 and the digital control terminals 140, 150, and 160. For example, DCL signals (V1_EN, V2_EN, V3_EN) generated by the digital control circuit 80 of the tracker circuit 2C are applied to the digital control terminals 140, 150, and 160.

Digital control signals supplied to the digital control terminals 140, 150, and 160 are not serial data signals such as digital control signals of a source-synchronous type but are parallel data signals. Since the DCL signals V1_EN, V2_EN, and V3_EN are supplied in a parallel manner to the digital control terminals 140, 150, and 160, respectively, rapid variable supply of power supply voltages and rapid switching between ON and OFF of the peak amplifiers 21, 22, 31, and 32 can be achieved. Thus, a wide channel band width of high frequency signals in a millimeter-wave band and a sub-terahertz band can be supported.

FIG. 5B is a diagram illustrating a logical value table for the logic circuits 14C, 24C, and 34C in Modification 3 and the relationship between a high frequency signal and a power supply voltage value. In part (a) of FIG. 5B, a power supply voltage (V1, V2, or V3) applied based on a DCL signal (V1_EN, V2_EN, V3_EN) to the power supply voltage terminal 130 is indicated, and a gate signal (Vg_C), a gate signal (Vg_P1), and a gate signal (Vg_P2) outputted based on the DCL signals (V1_EN, V2_EN, V3_EN) from the logic circuit 14C, the logic circuit 24C, and the logic circuit 34C, respectively, are indicated. Furthermore, in part (b) of FIG. 5B, a power supply voltage (V1, V2, or V3) supplied to the amplifier circuit 1C with respect to an envelope of a high frequency signal inputted to the amplifier circuit 1C is indicated.

As illustrated in FIG. 5B, when the DCL signal V1_EN is 1, the DCL signal V2_EN is 0, and the DCL signal V3_EN is 0, the voltage selection circuit 70 outputs the power supply voltage V1 to the power supply voltage terminal 130, the logic circuit 14C outputs a gate signal (Vg_C=1) that allows the switch 13 to be electrically connected, the logic circuit 24C outputs a gate signal (Vg_P1=0) that allows the switch 23 to be electrically disconnected, and the logic circuit 34C outputs a gate signal (Vg_P2=0) that allows the switch 33 to be electrically disconnected.

Furthermore, when the DCL signal V1_EN is 0, the DCL signal V2_EN is 1, and the DCL signal V3_EN is 0, the voltage selection circuit 70 outputs the power supply voltage V2, which is larger than the power supply voltage V1, to the power supply voltage terminal 130, the logic circuit 14C outputs a gate signal (Vg_C=1) that allows the switch 13 to be electrically connected, the logic circuit 24C outputs a gate signal (Vg_P1=1) that allows the switch 23 to be electrically connected, and the logic circuit 34C outputs a gate signal (Vg_P2=0) that allows the switch 33 to be electrically disconnected.

Furthermore, when the DCL signal V1_EN is 0, the DCL signal V2_EN is 0, and the DCL signal V3_EN is 1, the voltage selection circuit 70 outputs the power supply voltage V3, which is larger than the power supply voltage V2, to the power supply voltage terminal 130, the logic circuit 14C outputs a gate signal (Vg_C=1) that allows the switch 13 to be electrically connected, the logic circuit 24C outputs a gate signal (Vg_P1=1) that allows the switch 23 to be electrically connected, and the logic circuit 34C outputs a gate signal (Vg_P2=1) that allows the switch 33 to be electrically connected.

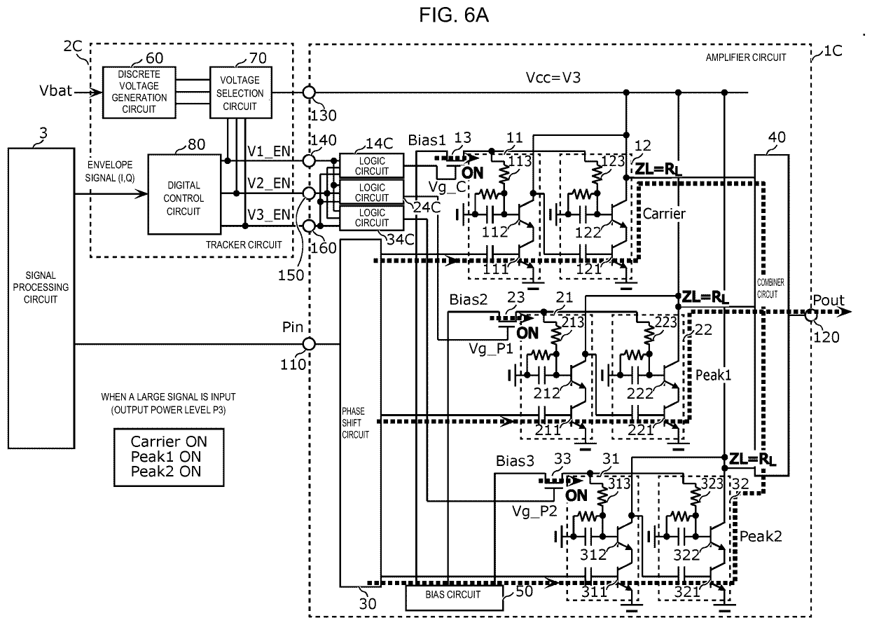

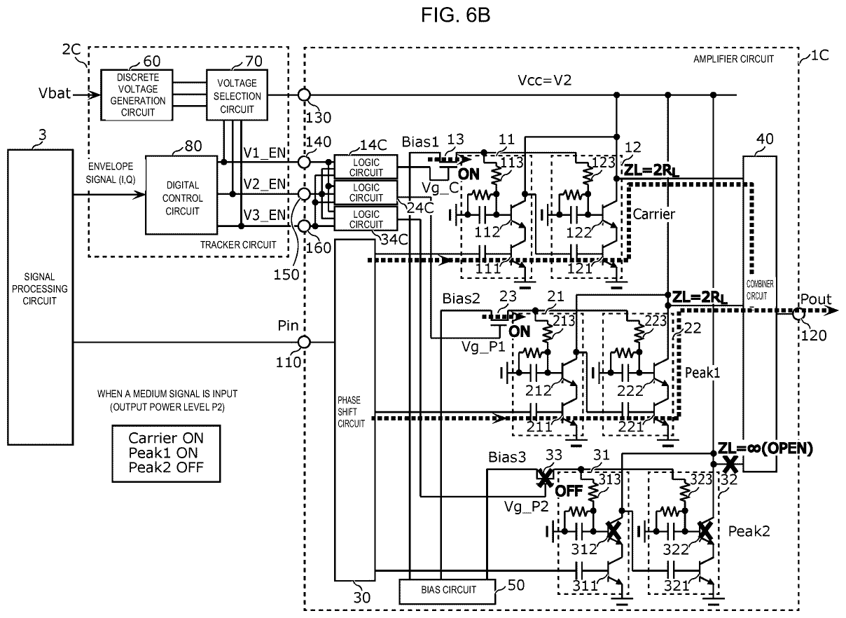

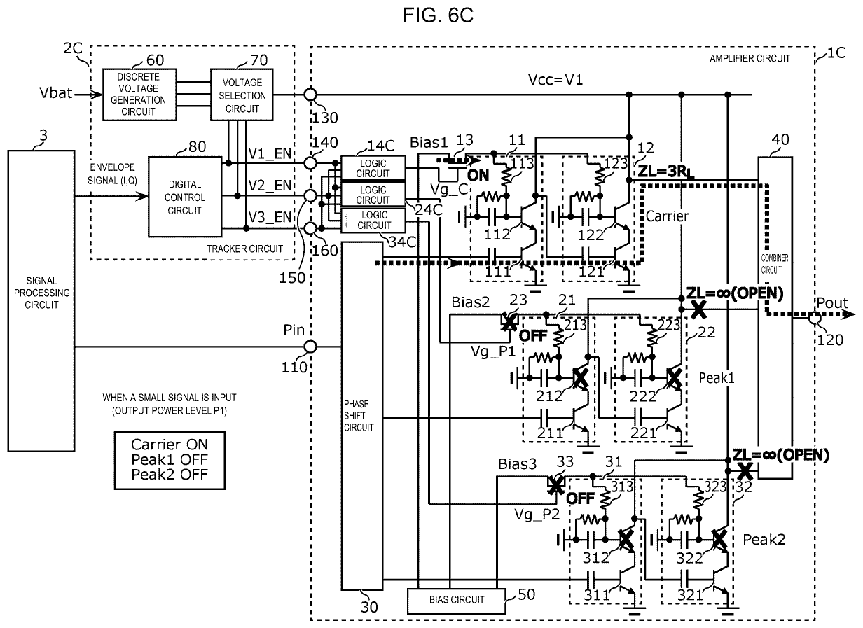

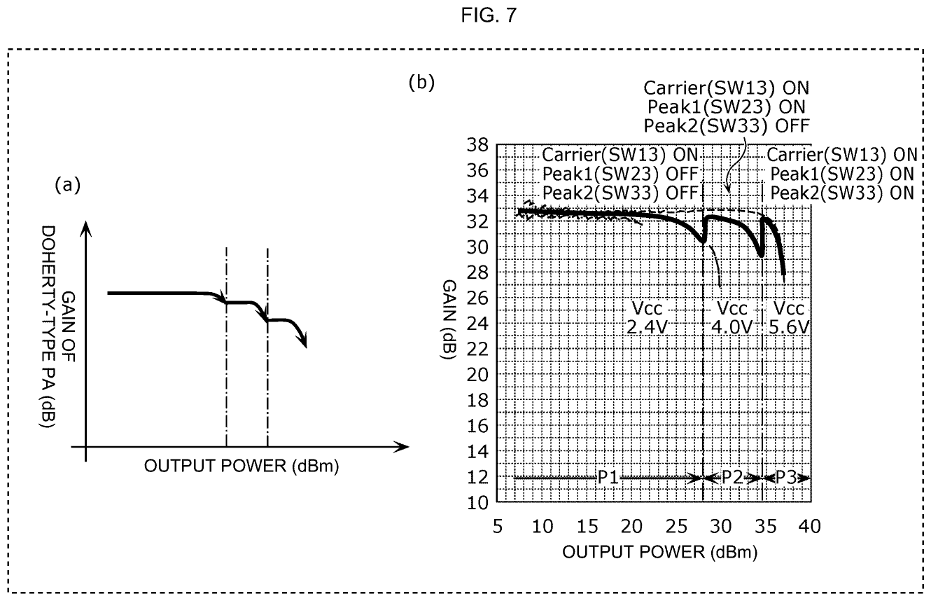

FIG. 6A is a circuit state diagram for the case where an input power of the amplifier circuit 1C according to Modification 3 has a third power value. As illustrated in the drawing, in the case where the envelope value (the square root of (I²+Q²)) of a high frequency signal inputted to the amplifier circuit 1C is relatively large (when a large signal is inputted: third power value), the amplifier circuit 1C receives the power supply voltage V3, and the switches 13, 23, and 33 become electrically connected. Accordingly, the carrier amplifiers 11 and 12 and the peak amplifiers 21, 22, 31, and 32 that are supplied with bias currents from the bias circuit 50 enter an ON state. In this case, an impedance when a load side is seen from output terminals of the carrier amplifier 12 and the peak amplifiers 22 and 32 is represented by R_{L}.

FIG. 6B is a circuit state diagram for the case where an input power of the amplifier circuit 1C according to Modification 3 has a second power value. As illustrated in the drawing, in the case where the envelope value (the square root of (I²+Q²)) of a high frequency signal inputted to the amplifier circuit 1C is smaller than the third power value (when a medium signal is inputted: second power value), the amplifier circuit 1C receives the power supply voltage V2, the switches 13 and 23 become electrically connected, and the switch 33 becomes electrically disconnected. Accordingly, the carrier amplifiers 11 and 12 and the peak amplifiers 21 and 22 that are supplied with bias currents from the bias circuit 50 enter an ON state, and the peak amplifiers 31 and 32 that are not supplied with a bias current from the bias circuit 50 enter an OFF state. In this case, an impedance when the load side is seen from the output terminals of the carrier amplifier 12 and the peak amplifier 22 is represented by 2R_{L}. At this time, an impedance when the load side is seen from the output terminal of the peak amplifier 32 is in an open state.

FIG. 6C is a circuit state diagram for the case where an input power of the amplifier circuit 1C according to Modification 3 has a first power value. As illustrated in the drawing, in the case where the envelope value (the square root of (I²+Q²)) of a high frequency signal inputted to the amplifier circuit 1C is smaller than the second power value (when a small signal is inputted: first power value), the amplifier circuit 1C receives the power supply voltage V1, the switch 13 becomes electrically connected, and the switches 23 and 33 become electrically disconnected. Accordingly, the carrier amplifiers 11 and 12 that are supplied with a bias current from the bias circuit 50 enter an ON state, and the peak amplifiers 21, 22, 31, and 32 that are not supplied with bias currents from the bias circuit 50 enter an OFF state. In this case, an impedance when the load side is seen from the output terminal of the carrier amplifier 12 is represented by 3R_{L}. At this time, an impedance when the load side is seen from the output terminals of the peak amplifiers 22 and 32 is in an open state.

As described above, when the power level of a high frequency input signal drops from the third power value (when a large signal is input) to the second power value (when a medium signal is input), the impedance when the load side is seen from the carrier amplifier 12 and the peak amplifier 22 that are in the ON state increases. Therefore, when a medium signal is inputted, a high efficiency can be achieved compared to the case where the carrier amplifier 12 and the peak amplifiers 22 and 32 are operating in the ON state.

Furthermore, when the power level of a high frequency input signal drops from the second power value (when a medium signal is input) to the first power value (when a small signal is input), the impedance when the load side is seen from the carrier amplifier 12 that is in the ON state further increases. Therefore, when a small signal is inputted, a high efficiency can be achieved compared to the case where the carrier amplifier 12 and the peak amplifier 22 are operating in the ON state.

That is, when a transition is made from a large signal input to a small signal input, the peak amplifier 32 and the peak amplifier 22 enter the OFF state in this order, and the impedance when the load side is seen from the carrier amplifier 12 (and a peak amplifier) in the ON state increases. Therefore, the amplifier circuit 1C can be caused to operate with high efficiency in a low output region (and a medium output region). Furthermore, since the peak amplifiers 22 and 32 change to the OFF state step by step, a backoff amount, which is the power difference between an output power in the state in which the peak amplifiers 22 and 32 are ON and an output power in the state in which the peak amplifiers 22 and 32 are OFF, can be ensured to be large.

In contrast, when a large signal is inputted, a large power signal can be outputted since the carrier amplifiers 11 and 12 and the peak amplifiers 21, 22, 31, and 32 operate in the state in which the power supply voltage is large (V3), and signal distortion can be suppressed since the impedance when the load side is seen from the peak amplifiers 22 and 32 is low.

Accordingly, since the supply of the first bias current to the peak amplifiers 21 and 22 and the supply of the second bias current to the peak amplifiers 31 and 32 are controlled on the basis of an envelope signal, efficiency is optimized based on an output power of the amplifier circuit 1C. Furthermore, since both the supply of a power supply voltage and switching between ON and OFF of the peak amplifiers 21, 22, 31, and 32 are performed on the basis of an envelope signal, the efficiency of the amplifier circuit 1C can be optimized with high accuracy.

A bias current is supplied, based on electrical connection and electrical disconnection of the switch 13, to the bases of the transistor 112 of the carrier amplifier 11 and the transistor 122 of the carrier amplifier 12.

Furthermore, a bias current is supplied, based on electrical connection and electrical disconnection of the switch 23, to the bases of the transistor 212 of the peak amplifier 21 and the transistor 222 of the peak amplifier 22. Furthermore, a bias current is supplied, based on electrical connection and electrical disconnection of the switch 33, to the bases of the transistor 312 of the peak amplifier 31 and the transistor 322 of the peak amplifier 32. In contrast, a bias current is continuously supplied to the bases of the transistor 111 of the carrier amplifier 11, the transistor 121 of the carrier amplifier 12, the transistor 211 of the peak amplifier 21, the transistor 221 of the peak amplifier 22, the transistor 311 of the peak amplifier 31, and the transistor 321 of the peak amplifier 32, regardless of whether the switches 13, 23, and 33 are electrically connected or electrically disconnected.

In part (b) of FIG. 7, a graph indicating the relationship between an output power and a gain of the amplifier circuit 1C according to Modification 3 is illustrated. Furthermore, in part (a) of FIG. 7, gain characteristics with respect to an output power of an amplifier circuit of a Doherty type to which digital ET is not applied is illustrated. In an amplifier circuit of a Doherty type, as a transition proceeds from a large signal input to a small signal input, an output impedance of an amplifier in an ON state increases, and an efficiency and a gain thus increase. In contrast, in an amplifier circuit to which digital ET is applied, as a transition proceeds from a small signal input to a large signal input, a gain increases, and a gain deviation with respect to an output power increases. That is, in the amplifier circuit 1C according to this modification, as illustrated in part (b) of FIG. 7, by combining the gain characteristics obtained in an amplifier circuit to which digital ET is applied and the gain characteristics obtained in an amplifier circuit of a Doherty type together, a gain deviation with respect to an output power can be reduced while a large backoff amount being ensured.

Also, in the amplifier circuits according to the embodiment and Modifications 1 to 3, by applying digital ET to an amplifier circuit of a Doherty type, a gain variation with respect to an output power can be suppressed, and a gain deviation can thus be reduced.

### (5 Effects and Others)

As described above, the amplifier circuit 1 according to the embodiment is an amplifier circuit that receives a plurality of discrete power supply voltages and includes the carrier amplifier 12, the peak amplifier 22, the combiner circuit 40 that combines a high frequency signal outputted from the carrier amplifier 12 and a high frequency signal outputted from the peak amplifier 22 together, the bias circuit 50 that supplies a first bias current to the peak amplifier 22, the digital control terminals 140 and 150 that receive a digital control signal based on an envelope signal, and the switch 23 that is connected to the digital control terminals 140 and 150 and switches between connection and disconnection between the bias circuit 50 and the peak amplifier 22. Each of the carrier amplifier 12 and the peak amplifier 22 includes a plurality of amplifier elements that are cascode-connected.

Accordingly, when a transition is made from a large signal input to a small signal input, the peak amplifier 22 enters an OFF state, and an impedance of the carrier amplifier 12 that is in an ON state increases. Therefore, the amplifier circuit 1 can be caused to operate with high efficiency in a low output region. In contrast, when a large signal is inputted, a large power signal can be outputted since the carrier amplifier 12 and the peak amplifier 22 operate in a state in which a power supply voltage is large, and signal distortion can be suppressed since an impedance when a load side is seen from the peak amplifier 22 is low. At this time, since the supply of the first bias current to the peak amplifier 22 is controlled on the basis of an envelope signal, efficiency is optimized based on an output power of the amplifier circuit 1, and a gain deviation with respect to an output power can be reduced by applying digital ET to the amplifier circuit 1 of a Doherty type.

Furthermore, for example, in the amplifier circuit 1, the digital control signal may be a digital signal different from a serial data signal.

Accordingly, since digital control signals are supplied in a parallel manner, rapid variable supply of power supply voltages and rapid switching between ON and OFF of the peak amplifier 22 can be achieved. Thus, a wide channel band width of high frequency signals in a millimeter-wave band and a sub-terahertz band can be supported.

Furthermore, for example, the amplifier circuit 1 may receive, based on the envelope signal, the plurality of discrete power supply voltages.

Accordingly, since both the supply of a power supply voltage and switching between ON and OFF of the peak amplifier 22 are performed on the basis of an envelope signal, the efficiency of the amplifier circuit 1 can be optimized with high accuracy.

Furthermore, for example, in the amplifier circuit 1, the switch 23 may be electrically disconnected when a power level of a high frequency signal inputted to the amplifier circuit 1 is a first power value, and the switch 23 may be electrically connected when the power level of the high frequency signal inputted to the amplifier circuit 1 is a second power value that is larger than the first power value.

Accordingly, in the case of the first power value, the peak amplifier 22 is in the OFF state, and the impedance of the carrier amplifier 12 is relatively large. Thus, in the case of the first power value, the efficiency of the amplifier circuit 1 can be improved.

Furthermore, for example, the amplifier circuit 1 further includes the signal input terminal 110 to which a high frequency signal is inputted, the power supply voltage terminal 130 to which a power supply voltage based on the envelope signal is inputted, and the digital control terminals 140 and 150 that are connected to the switch 23, the digital control signal being inputted to the digital control terminals 140 and 150. The carrier amplifier 12 includes the transistors 121 and 122. The base of the transistor 121 is connected to the signal input terminal 110, the emitter of the transistor 121 is connected to the ground, the collector of the transistor 121 is connected to the emitter of the transistor 122, the collector of the transistor 122 is connected to the power supply voltage terminal 130 and the combiner circuit 40, and the base of the transistor 122 is connected to the bias circuit 50. The peak amplifier 22 includes the transistors 221 and 222. The base of the transistor 221 is connected to the signal input terminal 110, the emitter of the transistor 221 is connected to the ground, the collector of the transistor 221 is connected to the emitter of the transistor 222, the collector of the transistor 222 is connected to the power supply voltage terminal 130 and the combiner circuit 40, and the base of the transistor 222 is connected to the switch 23.

Furthermore, for example, the amplifier circuit 1 may further include the logic circuits 14 and 24 that are connected between the switch 23 and the digital control terminals 140 and 150.

Accordingly, the digital control signal can be converted into a gate signal that controls electrical connection and electrical disconnection of the switch 23.

Furthermore, for example, in the amplifier circuit 1, a bias current may be supplied to the bases of the transistors 121 and 221 in both a state in which the switch 23 is electrically connected and a state in which the switch 23 is electrically disconnected.

Accordingly, the control of the ON state and the OFF state of the carrier amplifier 12 is performed only based on whether or not the bias current is supplied to the transistor 122, and the control of the ON state and the OFF state of the peak amplifier 22 is performed only based on whether or not the bias current is supplied to the transistor 222. Thus, a simplified control signal can be used.

Furthermore, for example, compared to the amplifier circuit 1, the amplifier circuit 1C according to Modification 3 may further include the peak amplifier 32 and the switch 33 that is connected to the digital control terminals 140, 150, and 160 and switches between connection and disconnection between the bias circuit 50 and the peak amplifier 32, the combiner circuit 40 may combine the high frequency signal outputted from the carrier amplifier 12, the high frequency signal outputted from the peak amplifier 22, and a high frequency signal outputted from the peak amplifier 32 together, the bias circuit 50 may supply the first bias current to the peak amplifier 22 and supply a second bias current to the peak amplifier 32, and each of the carrier amplifier 12 and the peak amplifiers 22 and 32 may include a plurality of amplifier elements that are cascode-connected.

Accordingly, when a transition is made from a large signal input to a small signal input, the peak amplifiers 32 and 22 enter the OFF state in this order, and an impedance when the load side is seen from the carrier amplifier 12 (and a peak amplifier) in the ON state increases. Therefore, the amplifier circuit 1C can be caused to operate with high efficiency in a low output region (and a medium output region). Furthermore, since the peak amplifiers 22 and 32 change to the OFF state step by step, a backoff amount, which is the power difference between an output power in a state in which the peak amplifiers 22 and 32 are ON and an output power in a state in which the peak amplifiers 22 and 32 are OFF, can be ensured to be large. In contrast, when a large signal is inputted, a large power signal can be outputted since the carrier amplifier 12 and the peak amplifiers 22 and 32 operate in a state in which the power supply voltage is large, and signal distortion can be suppressed since an impedance when the load side is seen from the peak amplifiers 22 and 32 is low. Accordingly, since the supply of the first bias current to the peak amplifier 22 and the supply of the second bias current to the peak amplifier 32 are controlled on the basis of an envelope signal, efficiency is optimized based on an output power of the amplifier circuit 1C, and a gain deviation with respect to the output power can be reduced by applying digital ET to the amplifier circuit 1C of a Doherty type.

Furthermore, for example, in the amplifier circuit 1C, the switches 23 and 33 are electrically disconnected in a case where a power level of the high frequency signal inputted to the amplifier circuit 1C is the first power value, the switch 23 is electrically connected and the switch 33 is electrically disconnected in a case where the power level of the high frequency signal inputted to the amplifier circuit 1C is the second power value that is larger than the first power value, and the switches 23 and 33 are electrically connected in a case where the power level of the high frequency signal inputted to the amplifier circuit 1C is a third power value that is larger than the second power value.

Accordingly, in the case of the second power value, the peak amplifier 32 is in the OFF state, and an impedance when the load side is seen from the carrier amplifier 12 and the peak amplifier 22 is relatively large. Furthermore, in the case of the first power value, the peak amplifiers 22 and 32 are in the OFF state, and the impedance when the load side is seen from the carrier amplifier 12 is further relatively large. Thus, with the first power value and the second power value, the efficiency of the amplifier circuit 1C is improved.

Furthermore, the communication apparatus 4 according to the embodiment includes the signal processing circuit 3 that processes a high frequency signal and the amplifier circuit 1 that transmits the high frequency signal between the signal processing circuit 3 and an antenna.

Accordingly, an effect of the amplifier circuit 1 can be achieved in the communication apparatus 4.

Furthermore, for example, the communication apparatus 4 may further include the tracker circuit 2 that supplies a power supply voltage to the amplifier circuit 1. The tracker circuit 2 may include the discrete voltage generation circuit 60 that is configured to generate a plurality of discrete voltages, the voltage selection circuit 70 that is configured to selectively output, based on an envelope signal, at least one of the plurality of discrete voltages to the amplifier circuit 1, and the digital control circuit 80 that outputs the digital control signal to the voltage selection circuit 70 and the switch 23.

### Other Embodiments

An amplifier circuit and a communication apparatus according to the present disclosure have been described above based on an embodiment and modifications. However, the amplifier circuit and the communication apparatus according to the present disclosure are not limited to the embodiment and the modifications described above. Other embodiments implemented by combining desired component elements in the embodiment and the modifications described above, modifications obtained by making various changes conceivable by those skilled in the art to the embodiment and the modifications described above without departing from the gist of the present disclosure, and various types of equipment including an amplifier circuit and a communication apparatus described above are also included in the present disclosure.

For example, in a circuit configuration of an amplifier circuit and a communication apparatus according to each of the embodiment and the modifications described above, a circuit element, a wire, and the like may be inserted between circuit elements and paths connecting signal paths disclosed in drawings.

Hereinafter, features of an amplifier circuit and a communication apparatus described above based on each of the embodiment and the modifications described above will be described below.

<1> An amplifier circuit that receives a plurality of discrete power supply voltages, the amplifier circuit comprising: a carrier amplifier; a first peak amplifier; a combiner circuit that combines a high frequency signal outputted from the carrier amplifier and a high frequency signal outputted from the first peak amplifier together; a bias circuit that supplies a first bias current to the first peak amplifier; a digital control terminal that receives a digital control signal based on an envelope signal; and a first switch that is connected to the digital control terminal and switches between connection and disconnection between the bias circuit and the first peak amplifier, wherein each of the carrier amplifier and the first peak amplifier includes a plurality of amplifier elements that are cascode-connected.

<2> The amplifier circuit according to <1>, wherein the digital control signal is a digital signal different from a serial data signal.

<3> The amplifier circuit according to <1>, wherein the amplifier circuit receives, based on the envelope signal, the plurality of discrete power supply voltages.

<4> The amplifier circuit according to any one of <1> to <3>, wherein, in a case where a power level of a high frequency signal inputted to the amplifier circuit is a first power value, the first switch is electrically disconnected, and wherein, in a case where the power level of the high frequency signal inputted to the amplifier circuit is a second power value that is larger than the first power value, the first switch is electrically connected.

<5> The amplifier circuit according to any one of <1> to <4>, further comprising: a signal input terminal to which a high frequency signal is inputted; a power supply voltage terminal to which a power supply voltage based on the envelope signal is inputted; and a digital control terminal that is connected to the first switch, the digital control signal being inputted to the digital control terminal, wherein the carrier amplifier includes a first amplifier element that includes a first control terminal, a first terminal, and a second terminal, and a second amplifier element that includes a second control terminal, a third terminal, and a fourth terminal, wherein the first control terminal is connected to the signal input terminal, wherein the first terminal is connected to a ground, wherein the second terminal is connected to the third terminal, wherein the fourth terminal is connected to the power supply voltage terminal and the combiner circuit, wherein the second control terminal is connected to the bias circuit, wherein the first peak amplifier includes a third amplifier element that includes a third control terminal, a fifth terminal, and a sixth terminal, and a fourth amplifier element that includes a fourth control terminal, a seventh terminal, and an eighth terminal, wherein the third control terminal is connected to the signal input terminal, wherein the fifth terminal is connected to the ground, wherein the sixth terminal is connected to the seventh terminal, wherein the eighth terminal is connected to the power supply voltage terminal and the combiner circuit, and wherein the fourth control terminal is connected to the first switch.

<6> The amplifier circuit according to <5>, further comprising: a logic circuit that is connected between the digital control terminal and the first switch.

<7> The amplifier circuit according to <5> or <6>, wherein a bias current is supplied to the first control terminal and the third control terminal in both a state in which the first switch is electrically connected and a state in which the first switch is electrically disconnected.

<8> The amplifier circuit according to any one of <1> to <7>, further comprising: a second peak amplifier; and a second switch that is connected to the digital control terminal and switches between connection and disconnection between the bias circuit and the second peak amplifier, wherein the combiner circuit combines the high frequency signal outputted from the carrier amplifier, the high frequency signal outputted from the first peak amplifier, and a high frequency signal outputted from the second peak amplifier together, wherein the bias circuit supplies the first bias current to the first peak amplifier and supplies a second bias current to the second peak amplifier, and wherein each of the carrier amplifier, the first peak amplifier, and the second peak amplifier includes a plurality of amplifier elements that are cascode-connected.

<9> The amplifier circuit according to <8>, wherein, in a case where a power level of a high frequency signal inputted to the amplifier circuit is a first power value, the first switch and the second switch are electrically disconnected, wherein, in a case where the power level of the high frequency signal inputted to the amplifier circuit is a second power value that is larger than the first power value, the first switch is electrically connected and the second switch is electrically disconnected, and wherein, in a case where the power level of the high frequency signal inputted to the amplifier circuit is a third power value that is larger than the second power value, the first switch is electrically connected and the second switch is electrically connected.

<10> A communication apparatus comprising: a signal processing circuit that processes a high frequency signal; and the amplifier circuit according to any one of <1> to <9> that transmits the high frequency signal between the signal processing circuit and an antenna.

<11> The communication apparatus according to <10>, further comprising: a tracker circuit that supplies a power supply voltage to the amplifier circuit, wherein the tracker circuit includes a discrete voltage generation circuit that is configured to generate a plurality of discrete voltages, a voltage selection circuit that is configured to selectively output, based on an envelope signal, at least one of the plurality of discrete voltages to the amplifier circuit, and a digital control circuit that outputs the digital control signal to the voltage selection circuit and the first switch.

The present disclosure is widely usable as a power amplifier circuit or a communication apparatus that is arranged in a front end section supporting multiple bands for communication equipment such as a mobile phone.
1, 1A, 1B, 1C amplifier circuit
2, 2A, 2B, 2C tracker circuit
3 signal processing circuit
4, 4A, 4B, 4C communication apparatus
11, 12 carrier amplifier
13, 23, 33 switch
14, 14C, 24, 24C, 34C, 74 logic circuit
21, 22, 31, 32 peak amplifier
30 phase shift circuit
40 combiner circuit
50 bias circuit
60 discrete voltage generation circuit
70 voltage selection circuit
80 digital control circuit
110 signal input terminal
111, 112, 121, 122, 211, 212, 221, 222, 311, 312, 321, 322 transistor
113, 123, 213, 223, 313, 323 resistor
120 signal output terminal
130 power supply voltage terminal
140, 150, 160 digital control terminal

1. An amplifier circuit configured to receive a plurality of discrete power supply voltages, the amplifier circuit comprising:
a carrier amplifier;
a first peak amplifier;
a combiner circuit configured to combine a high frequency signal outputted from the carrier amplifier and a high frequency signal outputted from the first peak amplifier together;
a bias circuit configured to supply a first bias current to the first peak amplifier;
a digital control terminal configured to receive a digital control signal based on an envelope signal; and
a first switch connected to the digital control terminal and configured to switch between connection and disconnection between the bias circuit and the first peak amplifier,
wherein each of the carrier amplifier and the first peak amplifier comprises a plurality of cascode-connected amplifier elements.

2. The amplifier circuit according to claim 1, wherein the digital control signal is a digital signal different from a serial data signal.

3. The amplifier circuit according to claim 1, wherein the amplifier circuit is configured to receive, based on the envelope signal, the plurality of discrete power supply voltages.

4. The amplifier circuit according to claim 1,
wherein, in a case where a power level of a high frequency signal inputted to the amplifier circuit is a first power value, the first switch is electrically disconnected, and
wherein, in a case where the power level of the high frequency signal inputted to the amplifier circuit is a second power value larger than the first power value, the first switch is electrically connected.

5. The amplifier circuit according to claim 1, further comprising:
a signal input terminal to which a high frequency signal is inputted; and
a power supply voltage terminal to which a power supply voltage based on the envelope signal is inputted,
wherein the carrier amplifier comprises:
a first amplifier element having a first control terminal, a first terminal, and a second terminal, and
a second amplifier element having a second control terminal, a third terminal, and a fourth terminal,
wherein the first control terminal is connected to the signal input terminal,
wherein the first terminal is connected to ground,
wherein the second terminal is connected to the third terminal,
wherein the fourth terminal is connected to the power supply voltage terminal and the combiner circuit,
wherein the second control terminal is connected to the bias circuit,
wherein the first peak amplifier comprises:
a third amplifier element having a third control terminal, a fifth terminal, and a sixth terminal, and
a fourth amplifier element having a fourth control terminal, a seventh terminal, and an eighth terminal,
wherein the third control terminal is connected to the signal input terminal,
wherein the fifth terminal is connected to ground,
wherein the sixth terminal is connected to the seventh terminal,
wherein the eighth terminal is connected to the power supply voltage terminal and the combiner circuit, and
wherein the fourth control terminal is connected to the first switch.

6. The amplifier circuit according to claim 5, further comprising:
a logic circuit connected between the digital control terminal and the first switch.

7. The amplifier circuit according to claim 5, wherein a bias current is supplied to the first control terminal and the third control terminal in both a state in which the first switch is electrically connected and a state in which the first switch is electrically disconnected.

8. The amplifier circuit according to claim 1, further comprising:
a second peak amplifier; and
a second switch connected to the digital control terminal and configured to switch between connection and disconnection between the bias circuit and the second peak amplifier,
wherein the combiner circuit is configured to combine the high frequency signal outputted from the carrier amplifier, the high frequency signal outputted from the first peak amplifier, and a high frequency signal outputted from the second peak amplifier together,
wherein the bias circuit is configured to supply the first bias current to the first peak amplifier and supply a second bias current to the second peak amplifier, and
wherein each of the carrier amplifier, the first peak amplifier, and the second peak amplifier comprises a plurality of cascode-connected amplifier elements.

9. The amplifier circuit according to claim 8,
wherein, in a case where a power level of a high frequency signal inputted to the amplifier circuit is a first power value, the first switch and the second switch are electrically disconnected,
wherein, in a case where the power level of the high frequency signal inputted to the amplifier circuit is a second power value larger than the first power value, the first switch is electrically connected and the second switch is electrically disconnected, and
wherein, in a case where the power level of the high frequency signal inputted to the amplifier circuit is a third power value larger than the second power value, the first switch is electrically connected and the second switch is electrically connected.

10. A communication apparatus comprising:
a signal processing circuit configured to process a high frequency signal; and
the amplifier circuit according to claim 1 configured to transmit the high frequency signal between the signal processing circuit and an antenna.

11. The communication apparatus according to claim 10, further comprising:
a tracker circuit configured to supply a power supply voltage to the amplifier circuit,
wherein the tracker circuit comprises:
a discrete voltage generation circuit configured to generate the plurality of discrete voltages;
a voltage selection circuit configured to selectively output, based on an envelope signal, at least one of the plurality of discrete voltages to the amplifier circuit; and
a digital control circuit configured to output the digital control signal to the voltage selection circuit and the first switch.

12. The amplifier circuit according to claim 2,
wherein, in a case where a power level of a high frequency signal inputted to the amplifier circuit is a first power value, the first switch is electrically disconnected, and
wherein, in a case where the power level of the high frequency signal inputted to the amplifier circuit is a second power value larger than the first power value, the first switch is electrically connected.

13. The amplifier circuit according to claim 3,
wherein, in a case where a power level of a high frequency signal inputted to the amplifier circuit is a first power value, the first switch is electrically disconnected, and
wherein, in a case where the power level of the high frequency signal inputted to the amplifier circuit is a second power value larger than the first power value, the first switch is electrically connected.

14. The amplifier circuit according to claim 6, wherein a bias current is supplied to the first control terminal and the third control terminal in both a state in which the first switch is electrically connected and a state in which the first switch is electrically disconnected.

15. The amplifier circuit according to claim 2, further comprising:
a second peak amplifier; and
a second switch connected to the digital control terminal and configured to switch between connection and disconnection between the bias circuit and the second peak amplifier,
wherein the combiner circuit is configured to combine the high frequency signal outputted from the carrier amplifier, the high frequency signal outputted from the first peak amplifier, and a high frequency signal outputted from the second peak amplifier together,
wherein the bias circuit is configured to supply the first bias current to the first peak amplifier and supply a second bias current to the second peak amplifier, and
wherein each of the carrier amplifier, the first peak amplifier, and the second peak amplifier comprises a plurality of cascode-connected amplifier elements.

16. The amplifier circuit according to claim 3, further comprising:
a second peak amplifier; and
a second switch connected to the digital control terminal and configured to switch between connection and disconnection between the bias circuit and the second peak amplifier,
wherein the combiner circuit is configured to combine the high frequency signal outputted from the carrier amplifier, the high frequency signal outputted from the first peak amplifier, and a high frequency signal outputted from the second peak amplifier together,
wherein the bias circuit is configured to supply the first bias current to the first peak amplifier and supply a second bias current to the second peak amplifier, and
wherein each of the carrier amplifier, the first peak amplifier, and the second peak amplifier comprises a plurality of cascode-connected amplifier elements.

17. The amplifier circuit according to claim 4, further comprising:
a second peak amplifier; and
a second switch connected to the digital control terminal and configured to switch between connection and disconnection between the bias circuit and the second peak amplifier,
wherein the combiner circuit is configured to combine the high frequency signal outputted from the carrier amplifier, the high frequency signal outputted from the first peak amplifier, and a high frequency signal outputted from the second peak amplifier together,
wherein the bias circuit is configured to supply the first bias current to the first peak amplifier and supply a second bias current to the second peak amplifier, and
wherein each of the carrier amplifier, the first peak amplifier, and the second peak amplifier comprises a plurality of cascode-connected amplifier elements.

18. The amplifier circuit according to claim 5, further comprising:
a second peak amplifier; and
a second switch connected to the digital control terminal and configured to switch between connection and disconnection between the bias circuit and the second peak amplifier,
wherein the combiner circuit is configured to combine the high frequency signal outputted from the carrier amplifier, the high frequency signal outputted from the first peak amplifier, and a high frequency signal outputted from the second peak amplifier together,
wherein the bias circuit is configured to supply the first bias current to the first peak amplifier and supply a second bias current to the second peak amplifier, and
wherein each of the carrier amplifier, the first peak amplifier, and the second peak amplifier comprises a plurality of cascode-connected amplifier elements.

19. The amplifier circuit according to claim 6, further comprising:
a second peak amplifier; and
a second switch connected to the digital control terminal and configured to switch between connection and disconnection between the bias circuit and the second peak amplifier,
wherein the combiner circuit is configured to combine the high frequency signal outputted from the carrier amplifier, the high frequency signal outputted from the first peak amplifier, and a high frequency signal outputted from the second peak amplifier together,
wherein the bias circuit is configured to supply the first bias current to the first peak amplifier and supply a second bias current to the second peak amplifier, and
wherein each of the carrier amplifier, the first peak amplifier, and the second peak amplifier comprises a plurality of cascode-connected amplifier elements.

20. The amplifier circuit according to claim 7, further comprising:
a second peak amplifier; and
a second switch connected to the digital control terminal and configured to switch between connection and disconnection between the bias circuit and the second peak amplifier,
wherein the combiner circuit is configured to combine the high frequency signal outputted from the carrier amplifier, the high frequency signal outputted from the first peak amplifier, and a high frequency signal outputted from the second peak amplifier together,
wherein the bias circuit is configured to supply the first bias current to the first peak amplifier and supply a second bias current to the second peak amplifier, and
wherein each of the carrier amplifier, the first peak amplifier, and the second peak amplifier comprises a plurality of cascode-connected amplifier elements.
